(19) United States
(12) Patent Application Publication
(10) Pub. No.: US 2007/0182026 A1
(43) Pub. Date: Aug. 9, 2007

(54) Semiconductor device

(75) Inventor: Shinichi Nishiura, Fussa-shi (JP)

Correspondence Address: KODA & ANDROLIA, 2029 CENTURY PARK EAST, SUITE 1140, LOS ANGELES, CA, 90067, US

(73) Assignee: Kabushiki Kaisha Shinkawa

(21) Appl. No.: 11/704,579

(22) Filed: Feb. 9, 2007

(30) Foreign Application Priority Data
Feb. 9, 2006 (JP) 2006-032032

(51) Int. Cl. H01L 23/52

(52) U.S. Cl. 257/784

(57) ABSTRACT

A semiconductor device having a plurality of pads P11, P12, P21, P22, P31, and P32 on the same plane of a semiconductor chip with wires W1, W2, and W3 connected between the pads P11 and P12, P21 and P22, and P31 and P32, respectively, so as to be electrically isolated from each other or without contacting each other. For the crossing and electrically isolated wires W1 and W2 respectively having pads P11 and P22 that are adjacently located very close, the wires are connected so that one pad P11 is set to be a first bonding point where a rising portion 12 of one wire W1 is bonded, and the other pad P22 is set to be a second bonding point to which a downwardly inclined end of the other wire W2 opposite from its cubic interchanging crossing and electrically isolated is bonded.

### BACKGROUND OF THE INVENTION

The present invention relates to a semiconductor device and more particularly to a semiconductor device having wires that cross each other.

Japanese Patent Application Unexamined Publication Disclosure Nos. H11 (1999)-87609 (Japanese Patent No. 3172473) and 2001-345339 (Japanese Patent No. 3370646) disclose semiconductor devices on which wires are provided so that some of them cross each other. In these patent publications, a plurality of semiconductor chips are disposed and fixed one on the other on a lead frame, and first bond points on pads near the periphery of each semiconductor chip and second bond points on leads of the lead frame are connected by wires. In a semiconductor device having such laminated semiconductor chips, such cases would occur that wires connected to a lower level semiconductor chip(s) (such wires called “lower wires”) and wires connected to an upper level semiconductor chip(s) (called “upper wires”) need to be crossed. When wires are crossed, it is likely that wires come into contact to each other (causing short-circuit), and this problem is resolved by inventions of the above-described patent publications.

In the art discussed above, connecting with wires between pads near the peripheries of laminated semiconductor chips and leads is made. In such a structure, even if the lower wires and upper wires are crossed, since the upper wires are deployed above the lower wires, wire contacts can be prevented comparatively easily. Recently, however, due to the increasing trend toward even higher circuit densities in semiconductor chips, pads are provided not only near the peripheries of semiconductor chips but also in the central areas of semiconductor chips. In such semiconductor devices, it is necessary to execute pad-to-pad wire bonding on a semiconductor chip.

### BRIEF SUMMARY OF THE INVENTION

Accordingly, it is a first object of the present invention to provide a semiconductor device in which pads deployed in a planar fashion on a semiconductor chip are connected with wires that cross one another and electrically isolated from each other.

When pads on the same surface of a semiconductor chip are connected with wires that cross each other, there is no upper-lower relationship in pads and wires such as lower wires and upper wires as discussed above; accordingly, it is necessary to prevent wires from contacting each other and to keep the wire loop height as low as possible.

It is, therefore, another object of the present invention to provide a semiconductor device in which even if wires connecting the pads cross one another, wires are electrically isolated from each other so that wire contacts are prevented, and the wire loop height is set to be low.

The above objects are accomplished by a unique structure of the present invention for a semiconductor device, and in the semiconductor device of the present invention, a plurality of pads are provided on the same plane of a semiconductor chip having pads comprised of pairs thereof, and a plurality of wires are each bonded from one pad to another pad with at least one of the wires crossing at least other one of the wires and electrically isolated therefrom.

In the semiconductor device of the present invention described above, the crossing and electrically isolated wires are bonded with one of the pads being a first bonding point and another being a second bonding point when the pads of the crossing and electrically isolated wires are closely adjacent to each other.

Furthermore, in the semiconductor device of the present invention of the above structure, each of the wires includes
a bonded ball formed at a first bonding point to bond a ball formed by means of a wire bonding apparatus;
a rising portion formed on the bonded ball;
an inclined portion extending straight through from one of a bended portion and the top of the rising portion to a second bonding point, the bended portion being formed between the top of the rising portion and the second bonding point; and
at least one of a concave portion downward, a convex portion upward, and a combination thereof between the top of the rising portion and the bended portion to prevent the wires from contacting each other, the height of the crossing and electrically isolated wires each being substantially equal to or lower than the height of the rising portion.

In addition, in the semiconductor device of the present invention of the above structure, the second bonding point is formed beforehand with a bump.

As seen from the above, the present invention provides a semiconductor device in which pads deployed on the same plane are connected by wires that cross one another and electrically isolated from each other or without contacting each other in a vertical direction.

In addition, when pads for wires that cross each other are deployed adjacent very closely, wires are connected with one pad being a first bond point and the other pad a second bond point, so that wire loop height of wires can be made low.

Furthermore, since the height of crossing wires is set to be equal to or below the height of the rising portion of the wire, the overall loop height of wires can be formed low.

In addition, since a bump is formed beforehand on the second bond point, a strong wire bonding force is obtained, and the pads are difficult to be scratched.

### BRIEF DESCRIPTION OF THE SEVERAL VIEWS OF THE DRAWINGS

FIG. 1 is a perspective view of a first embodiment for the semiconductor device of the present invention.

FIG. 2 is a perspective view of a second embodiment for the semiconductor device of the present invention.

FIG. 3 is a perspective view of a third embodiment for the semiconductor device of the present invention.

FIG. 4 is a perspective view of a fourth embodiment for the semiconductor device of the present invention.

FIG. 5 is a perspective view of a fifth embodiment for the semiconductor device of the present invention.

FIG. 6 is a perspective view of a sixth embodiment for the semiconductor device of the present invention.

### DETAILED DESCRIPTION OF THE INVENTION

Hereinafter, preferred embodiments of the present invention will be concretely described with reference to the accompanying drawings.

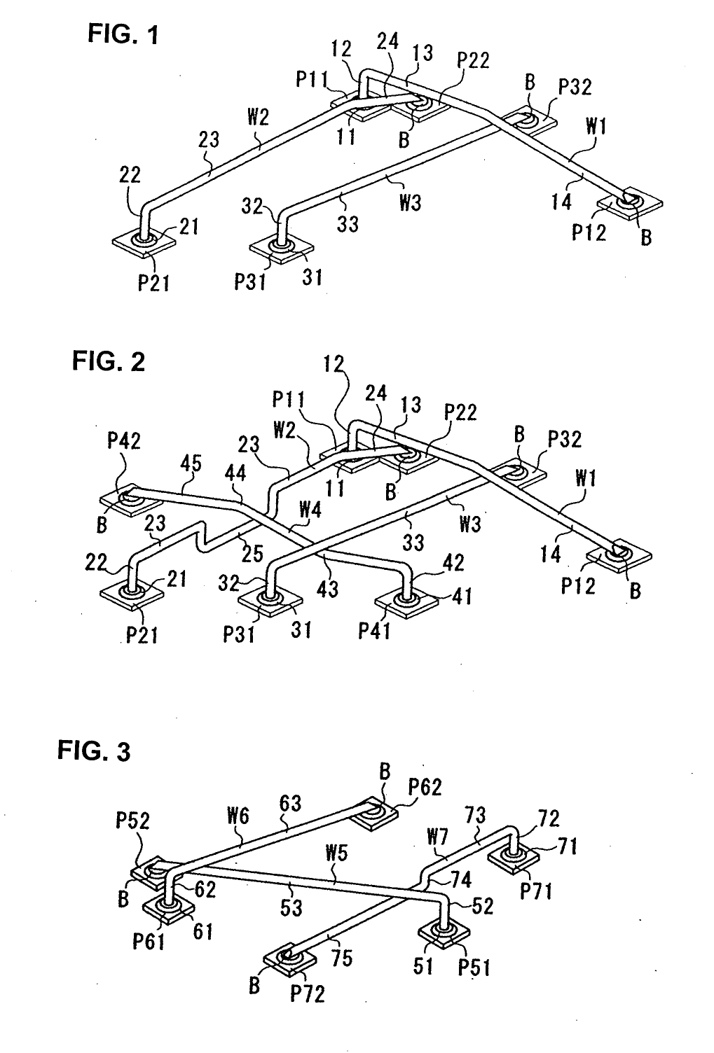

The first embodiment of the present invention for a semiconductor device will be described with reference to FIG. 1. In this semiconductor device, wires are crossed such that two wires W2 and W3 cross one wire W1 and are electrically isolated from the wire W1. More specifically, the wire W1 is connected to pads P11 and P12, the wire W2 is connected to pads P21 and P22, and the wire W3 is connected to the pads P31 and P32 so as to be electrically isolated from each other or without contacting each other. The pads P11, P12, P21, P22, P31, and P32 are provided on the upper surface of a semiconductor chip so that they are all on the same plane on a semiconductor chip (not shown).

In wire bonding for the above-described structure, to a first bond point, a ball formed at a tip of one end of a wire passing through a capillary (not shown) is bonded so that a bonded ball is formed, and, to a second bond point, the other end of the wire is bonded. The wire loop shape of such a bonded wire is such that a rising portion is formed on the bonded ball (to extend upward) at the first bond point, and a portion of the wire near the second bond point is inclined downward so as to be low in height.

In the above structure, the pads P11 and P22 for the respective crossing wires W1 and W2 are closely adjacent to each other. Accordingly, one of the pads P11 or P22 is set to be a first bonding point, and the other is set to be a second bonding point, so that contact between the wires W1 and W2 is prevented. More specifically, in the structure of FIG. 1, the pad P11 is the first bonding point for the wire W1, and the pad P22 is the second bonding point for the wire W2. As a result, as described above, the wire W1 has a rising portion 12 on the pad P11 which is the first bonding point (and an inclined portion 14 of which end is bonded to the pad P12 which is the second bonding point), and the portion of the wire W2 near the pad 22 which is the second bonding point is inclined downward so as to have an inclined portion 24 and to be low (and the other end of the wire W2 has a rising portion 22 rising upward from the pad P21 which is the first bonding point).

As for the pads P31 and P32 for the wire W3, either pad can be set as a first bonding point; however, the pad P32 is closer to the pad P11, which is the first bonding point for the wire W1, than the pad P12, which is the second bonding point for the wire W1. Accordingly, the pad P32 is set to be a second bonding point for the wire W3 so that the wire W3 is prevented from contacting the wire W1.

As seen from the above, in the structure of FIG. 1, the pads P12, P22, and P32 are the second bonding points. Here, when a wire is directly bonded to a pad that is a second bonding point, the bonding force of such a wire tends to be weak, and the pad could be easily scratched. Accordingly, so as to prevent such problems, bumps B are formed on the pads P12, P22, and P32 beforehand.

Connection (bonding) of the wires W1, W2, and W3 are executed as described below. In wire bonding connections with these wires, the second bonding points for the wires W2 and W3 (or the pads P22 and P32) are located on the pad P11 side; accordingly, it is preferable that portions of the wires W2 and W3 near the wire W1 be formed lower than the wire W1 so as to avoid contact. Thus, the wire W1 is connected after connecting the wires W2 and W3.

More specifically, first, the wire W2 is connected such that, after forming a bonded ball 21 on the pad P21 that is the first bonding point, a rising portion 22, a horizontal portion 23 that is substantially horizontal (or substantially parallel to the surface of the semiconductor chip on which the pads and wires are provided), and an inclined portion 24 are formed, and the tip end of inclined portion 24 of the wire W2 is connected (bonded) to a bump B formed on the pad P22 which is the second bonding point. A portion of the wire W2 between the top of the rising portion 22 and the second bonding point (pad P22) forms a bended portion.

The wire W3 is next connected. The wire W3 is connected in a similar manner to the wire W2, so that, after forming a bonded ball 31 on the pad P31 which is the first bonding point, a rising portion 32 and an (downwardly) inclined portion 33 are formed, and the tip end of the inclined portion 33 of the wire W3 is connected (bonded) to a bump B formed on the pad P32 which is the second bonding point.

The wire W1 is lastly connected, similarly, such that, after forming a bonded ball 11 on the pad P11 which is the first bonding point, a rising portion 12, a horizontal portion 13 that is substantially horizontal and at substantially right angles with respect to the wires W2 and W3, and an (downwardly) inclined portion 14 are formed, and the tip end of the inclined portion 14 is connected (bonded) to a bump B formed on the pad P12 which is the second bonding point. A portion of the wire W1 between the top of the rising portion 12 and the second bonding point (pad P12) forms a bended portion. In this wire W1, the horizontal portion 13 and inclined portion 14 are provided so as to be above the wires W2 and W3 with a height sufficient to not contact the wires W2 and W3.

As seen from the above, for the crossing wires W1 and W2, when there are closely adjacent pads P11 and P22 present, one of them, pad P11, for example, is set to be a first bonding point, and the other, pad P22, for example, is set to be a second bonding point, so that the wire loop height of the wires W1, W2, and W3 can be low. Furthermore, the height of the respective wires W2, W2, and W3 is set to be at (equal to) or below the heights of the rising portions 12, 22, and 32 of the wires W2, W2, and W3; accordingly, the overall loop height of the wires W1, W2, and W3 can be low.

FIG. 2 shows the second embodiment of the semiconductor device of the present invention. In the structure of FIG. 2, a wire W4 is further provided for the structure of FIG. 1 so that it crosses the wires W2 and W3 and is electrically isolated from the wires W2 and W3.

More specifically, the pads P41 and P42 for the wire W4 are located away from the pads P21 and P31 for the wires W2 and W3; accordingly, either of the pads P41 and P42 can be either a first bonding point or a second bonding point. Since the wire W2 is provided below the wire W4, the portion of the wire W2 corresponding to the wire W4 is formed with a lowed wire portion 25 which is depressed downward. Furthermore, the wire W4 is provided below the wire W3; accordingly, the wires W1, W2, W3, and W4 are bonded in the order of W2, W4, W3, and then W1. The formation of the wires W1 and W2, which include the bended points, and the formation of the wire W3 are the same as in the above-described first embodiment of FIG. 1 except that the wire W2 has the lowered wire portion 25; and therefore, no further detailed description thereof will be given below.

First of all, the wire W2 is bonded between pads P21 and P22 with the lowered wire portion 25 formed. Next, the wire W4 is bonded between pads P41 and P42. The formation (bonding) of this wire W4 is performed such that, after a bonded ball 41 is formed on the pad 41 which is the first bonding point, a rising portion 42, a valley portion 43 depressed downward so as not to contact the corresponding portion of the wire W3, a peak portion 44 protruding upward in a peak shape so as not to contact the lowered wire portion 25 of the wire W2, and an (downwardly) inclined portion 45 are formed, and then the tip end of the inclined portion 45 of the wire W4 is bonded to a bump B formed on the pad P42 which is the second bonding point. By forming (bonding) the wires in this manner, the overall height of the wires W1, W2, W3, and W4 can be formed low.

FIG. 3 shows the third embodiment of the semiconductor device of the present invention. In this structure of FIG. 3, the configuration is substantially the same as that of the first embodiment of FIG. 1 including the bended portions. In other words, two wires W6 and W7 are connected such that they cross one wire W5 and are electrically isolated therefrom. The wire W5 is connected to pads P51 and P52, the wire W6 is connected to pads P61 and P62, and the wire W7 is connected to pads P71 and P72.

In this structure, the pads P52 and P61 for the crossing wires W5 and W6 are adjacently located very close. Accordingly, one of the pads P52 and P61 is set to be a first bonding point, and the other is set to be a second bonding point, thus preventing contact between the wires W5 and W6. More specifically, in the structure of FIG. 3, the pad P61 is the first bonding point for the wire W6 so that wire 6 has a rising portion 62 extending upward from pad 61, and the pad P52 is the second bonding point for the wire W5 so that the end of the wire 5 from the rising portion 62 is bonded thereto. As for the pads P71 and P72 for the wire W7, both are located away from the pad P51; accordingly, either can be set as a first bonding point; and in the shown structure, the pad P71 is selected as the first bonding point.

The wires W5, W6, and W7 are connected in the manner as described below. Since the pad P52 is a second bonding point, the wire W5 has to be formed lower than the wire W6. Furthermore, the wire W7 is positioned on the first bonding point side (or the pad P51 side) of the wire W5; accordingly, it is preferred that the wire W7 be formed lower than (or provided below) the wire W5. The wires W5, W6, and W7 are connected (bonded) in the order of W7, W5 and W6.

First of all, the wire W7 is connected (bonded) such that, after forming a bonded ball 71 on the pad P71 which is the first bonding point, a rising portion 72, a horizontal portion 73 that is substantially horizontal, a descending portion 74 that descends so that the portion corresponding to the wire W5 becomes low (or becomes lower than wire 5), and an (downwardly) inclined portion 75 are formed, and the tip end of the inclined portion 75 of the wire W7 is connected to a bump B formed on the pad P72 which is the second bonding point. A portion of the wire W7 between the top of the rising portion 72 and the second bonding point (pad P72) forms a bended portion.

The wire W5 is next connected in a similar manner to wire W7 such that, after forming a bonded ball 51 on the pad P51 which is the first bonding point, a rising portion 52 and an (downwardly) inclined portion 53 are formed, and the tip end of the inclined portion 53 of the wire W5 is connected to a bump B formed on the pad P52 which is the second bonding point.

The wire W6 is connected lastly similarly such that, after forming a bonded ball 61 on the pad P61 which is the first bonding point, a rising portion 62 and an (downwardly) inclined portion 63 are formed, and the tip end of the inclined portion 63 of the wire W6 is connected to a bump B formed on the pad P62 which is the second bonding point.

In this structure of FIG. 3 as well, when, for the crossing and electrically isolated wires W5 and W6, there are closely adjacent pads P52 and P61 present, then one of the pad, the pad P61, for example, is set to be the first bonding point, and the other, the pad P52, for example, is set to be the second bonding point, so that the loop height of the respective wires W5, W6, and W7 can be made low. Furthermore, since the height of the respective wires W5, W6, and W7 can be at (equal to) or below the heights of the rising portions 52, 62, and 72, the overall loop height of the respective wires W5, W6, and W7 can be formed low.

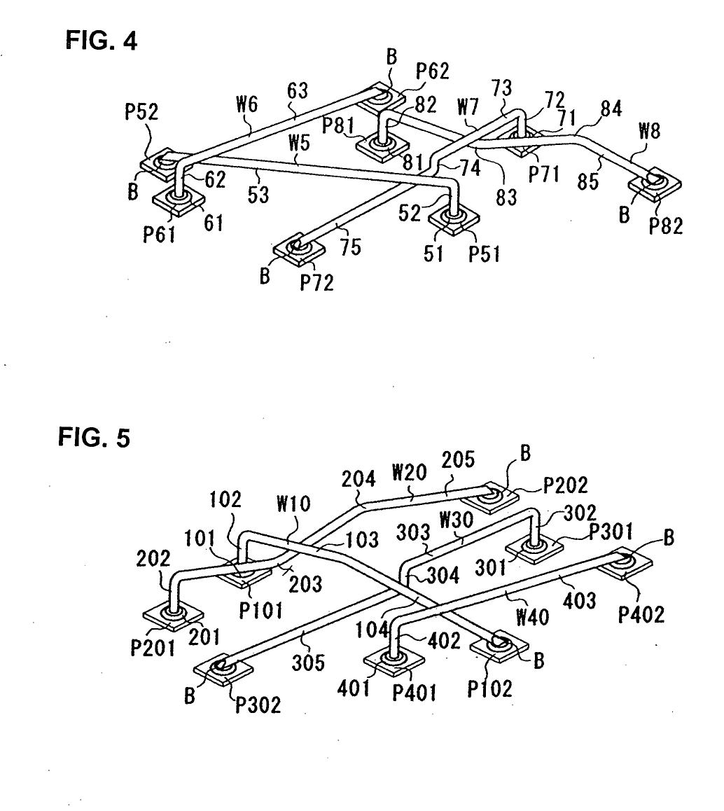

FIG. 4 shows the fourth embodiment of the semiconductor device of the present invention. In the structure of FIG. 4, a wire W8 is added to the structure of FIG. 3 so that it crosses a wire W7 and is electrically isolated therefrom. The pads P81 and P82 for the wire W8 that crosses the wire W7 are distant from the pads P71 and P72 for the wire W7; accordingly, either of the pads P81 and P82 can be either the first bonding point or the second bonding point. In the shown structure, since the wire W8 is provided below the wire W7, the wire W8 is first connected, and then other wires are connected in the same order as in the above-described third embodiment, that is, in the order of W7, W5, and W6.

The formation of the wire W7, which include the bended point, and the formation of wires W5 and W6 and are the same as that in the above-described third embodiment; accordingly, only the formation of the wire W8 will be described. After forming a bonded ball 81 on the pad P81 which is the first bonding point, a rising portion 82, a valley portion 83 depressed downward so that the portion corresponding to the horizontal portion 73 of the wire W7 is not contacted, a peak portion 84 protruding upward in a peak shape, and an (downwardly) inclined portion 85 are formed, and then the tip end of the inclined portion 85 of the wire W8 is connected to a bump B formed on the pad P82 which is the second bonding point. By connecting the wires in this way, the overall height of the wires W5, W6, W7, and W8 can be low.

FIG. 5 shows the fifth embodiment of the semiconductor device of the present invention. In the above-described first and third embodiments (FIG. 1 and FIG. 3), wires are connected so that two wires cross one wire. In the structure of FIG. 5, wires are connected so that three wires W20, W30, and W40 cross one wire W10 and are electrically isolated from the wire W10.

In the structure of FIG. 5, none of the pads P201, P202, P301, P302, P401, and P402 which are for the wires W20, W30, and W40 are closely adjacent to the pads P101 or P102 for the wire W10. Accordingly, the overall height of the wires W10, W20, W30, and W40 is formed low with such a configuration that the wires W20 and W30 are set to be below the wire W10, and the wire W40 is above the wire W10. Furthermore, the pad P102 for the wire W10 is closely located to the pad P401 for the wire W40 and is thus set to be a second bonding point.

In the structure of FIG. 5, the wires are connected in the order of W20, W30, W10, and W40.

More specifically, the wire W20 is first connected such that, after forming a bonded ball 201 on the pad P201 which is the first bonding point, a rising portion 202, a valley portion 203 depressed downward so that the portion corresponding to the horizontal portion 103 of the wire W10 does not make contact thereto, a peak portion 204 protruding upward in a peak shape, and an (downwardly) inclined portion 205 are formed, and the tip end of the inclined portion 205 of the wire W20 is connected to a bump B formed on the pad P202 which is the second bonding point. A portion of the wire W20 between the top of the rising portion 202 and the second bonding point (pad P202) forms a bended portion.

The wire W30 is connected next in a similar manner to the wire W20 such that, after forming a bonded ball 301 on the pad P301 which is the first bonding point, a rising portion 302, a horizontal portion 303 that is substantially horizontal, a descending portion 304 that descends so that the portion corresponding to the wire W10 becomes lower than the wire 10, and an (downwardly) inclined portion 305 are formed, and the tip end of the inclined portion 305 of the wire W30 is connected to a bump B formed on the pad P302 which is the second bonding point. A portion of the wire W30 between the top of the rising portion 302 and the second bonding point (pad P302) forms a bended portion.

Then, the wire W10 is connected similarly such that, after forming a bonded ball 101 on the pad P101 which is the first bonding point, a rising portion 102, a horizontal portion 103 that is substantially horizontal, and an (downwardly) inclined portion 104 are formed, and the tip end of the inclined portion 104 of the wire W10 is connected to a bump B formed on the pad P102 which is the second bonding point. A portion of the wire W10 between the top of the rising portion 102 and the second bonding point (pad P102) forms a bended portion.

The wire W40 is finally connected similarly such that, after forming a bonded ball on the pad P401 which is the first bonding point, a rising portion 402 and an (downwardly) inclined portion 403 are formed, and the tip end of the inclined portion 403 of the wire W40 is connected to a bump B formed on the pad P402 which is the second bonding point.

In this manner, the height of the respective connected (bonded) wires W110, W20, W30, and W40 can be at (equal to) or below the heights of the rising portions 102, 202, 302, and 402. Accordingly, the overall loop height of the wires W10, W20, W30, and W40 can be low.

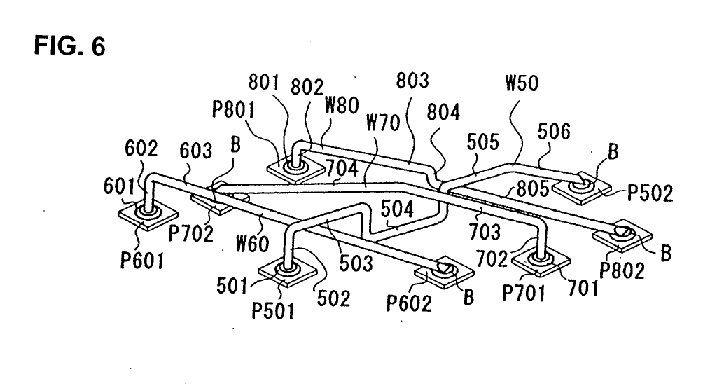

FIG. 6 shows the sixth embodiment of the semiconductor device of the present invention. In the structure of FIG. 6, as in the above-described embodiment of FIG. 5, wires are connected (bonded) so that three wires W60, W70, and W80 cross one wire W50 and are electrically isolated therefrom.

In this structure as well, none of the pads P601, P602, P701, P702, P801, and P802 for the wires W60, W70, and W80 are closely adjacent to the pads P501 or P502 of the wire W50. Accordingly, the overall height of the wires W50, W60, W70, and W80 can be formed low with such a configuration that the wires W60 and W80 are below the wire W50, and the wire W70 is above the wire W50.

In this embodiment, the wires are connected in the order of W60, W80, W50, and then W70.

More specifically, the wire W60 is first formed such that, after forming a bonded ball 601 on the pad P601 which is the first bonding point, a rising portion 602 and an (downwardly) inclined portion 603 are formed, and the tip end of the inclined portion 603 of the wire W60 is connected to a bump B formed on the pad P602 which is the second bonding point.

The wire W80 is next connected in a similar manner to the wire W60 such that, after forming a bonded ball 801 to the pad P801 which is the first bonding point, a rising portion 802, and a horizontal portion 803 that is substantially horizontal, are formed, and further a descending portion 804 that descends so that the portion corresponding to the wire W50 is low, and an (downwardly) inclined portion 805 are formed, and then the tip end of the inclined portion 805 of the wire W80 is connected to a bump B formed on the pad P802 which is the second bonding point. A portion of the wire W80 between the top of the rising portion 802 and the second bonding point (pad P802) forms a bended portion.

The wire W50 is connected next similarly such that, after forming a bonded ball 501 on the pad P501 which is the first bonding point, a rising portion 502, and a horizontal portion 503 that is substantially horizontal, are formed, and after which a lowered wire portion 504 where the portion corresponding to the wire W70 is depressed downward is formed so as to avoid contact with the W70, and a horizontal portion 505 where the portion corresponding to the wire W80 is at substantially the same height as the horizontal portion 503 is formed, after that an (downwardly) inclined portion 506 is formed, and the tip end of the inclined portion 506 of the wire W50 is connected to a bump B formed on the pad P502 which is the second bonding point. A portion of the wire W50 between the top of the rising portion 502 and the second bonding point (pad P502) forms a bended portion.

The wire W70 is lastly connected similarly such that, after forming a bonded ball 701 on the pad P701 which is the first bonding point, a rising portion 702, a horizontal portion 703 that is substantially horizontal, and an (downwardly) inclined portion 704 are formed, and the tip end of the inclined portion 704 of the wire W70 is connected to a bump B formed on the pad P702 which is the second bonding point. A portion of the wire W70 between the top of the rising portion 702 and the second bonding point (pad P702) forms a bended portion.

In this manner, since the height of the respective wires W50, W60, W70, and W80 can be at (equal to) or below the heights of the rising portions 502, 602, 702, and 802, the overall loop height of the wires W50, W60, W70, and W80 can be low.

In the embodiments described above, although the bumps are formed beforehand on the second bonding points, bumps cannot be necessarily formed on the second bonding points in the present invention. However, with bumps formed beforehand on the second bonding points as in the shown embodiments, a greater bonding strength for the wires is obtainable, and in addition the pads are difficult to be scratched. Thus, a preferable wire bonding is obtained. Furthermore, in the above-described embodiments, two or more wires cross one other wire; however, needless to say, the present invention is applicable in cases where only one wire crosses other one wire.

In the above-described embodiments, every bonding is performed by means of a wire bonding apparatus and by applying ultrasonic waves, heat, or pressing force or a combination thereof.

1. A semiconductor device comprising:
a plurality of pads provided on a same plane of a semiconductor chip, said pads being comprised of pairs thereof; and
a plurality of wires each bonded from one pad to another pad with at least one of said wires crossing at least other one of said wires and electrically isolated therefrom.

2. The semiconductor device according to claim 1, wherein said crossing and electrically isolated wires are bonded with one of said pads being a first bonding point and another being a second bonding point when said pads of said crossing and electrically isolated wires are closely adjacent to each other.

3. The semiconductor device according to claim 1, wherein said crossing and electrically isolated wires each including
a bonded ball formed at a first bonding point to bond a ball formed by means of a wire bonding apparatus;
a rising portion formed on said bonded ball;
an inclined portion extending straight through from one of a bended portion and a top of said rising portion to a second bonding point, said bended portion being formed between said top of said rising portion and said second bonding point; and
at least one of a concave portion downward, a convex portion upward, and a combination thereof between said top of said rising portion and said bended portion to prevent said wires from contacting each other, a height of said crossing and electrically isolated wires each being substantially equal to or lower than a height of said rising portion.

4. The semiconductor device according to claim 2, wherein said crossing and electrically isolated wires each including
a bonded ball formed at said first bonding point to bond a ball formed by means of a wire bonding apparatus;
a rising portion formed on said bonded ball;
an inclined portion extending straight through from one of a bended portion and a top of said rising portion to said second bonding point, said bended portion being formed between said top of said rising portion and said second bonding point; and
at least one of a concave portion downward, a convex portion upward, and a combination thereof between said top of said rising portion and said bended portion to prevent said wires from contacting each other, a height of said crossing and electrically isolated wires each being substantially equal to or lower than a height of said rising portion.

5. The semiconductor device according to claim 2, wherein said second bonding point is formed beforehand with a bump.

6. The semiconductor device according to claim 3, wherein said second bonding point is formed beforehand with a bump.

7. The semiconductor device according to claim 2, wherein every bonding is performed by means of a wire bonding apparatus by applying at least one selected from the group consisting of ultrasonic waves, heat, pressing force, and a combination thereof.

8. The semiconductor device according to claim 3, wherein every bonding is performed by means of a wire bonding apparatus by applying at least one selected from the group consisting of ultrasonic waves, heat, pressing force, and a combination thereof.
